(19) United States
(12) Patent Application Publication
(10) Pub. No.: US 2025/0022714 A1
(43) Pub. Date: Jan. 16, 2025

(54) CYCLIC ETCH OF SILICON OXIDE AND SILICON NITRIDE

(71) Applicant: Applied Materials, Inc., Santa Clara, CA (US)

(72) Inventors: Sonam Dorje Sherpa, San Ramon, CA (US); Iljo Kwak, Santa Clara, CA (US); Kenji Takeshita, Sunnyvale, CA (US); Alok Ranjan, San Ramon, CA (US)

(73) Assignee: Applied Materials, Inc., Santa Clara, CA (US)

(21) Appl. No.: 18/221,505

(22) Filed: Jul. 13, 2023

(51) Int. Cl. H01L 21/3065; C09K 13/08

(52) U.S. Cl. CPC H01L 21/3065; C09K 13/08

(57) ABSTRACT

Exemplary semiconductor processing methods may include flowing a fluorine-containing precursor and a hydrogen-containing precursor into a processing region of a semiconductor processing chamber. A substrate may be positioned within the processing region. The substrate may include a trench formed through stacked layers including alternating layers of silicon nitride and silicon oxide. The methods may include forming plasma effluents of the fluorine-containing precursor and the hydrogen-containing precursor and contacting the substrate with the plasma effluents of the fluorine-containing precursor and the hydrogen-containing precursor to form a fluorinated portion of the stacked layers. The methods may include flowing an inert precursor into the processing region, forming plasma effluents of the inert precursor, and contacting the substrate with the plasma effluents of the inert precursor to remove the fluorinated portion of the stacked layers. The methods may be performed at a temperature of less than or about 20° C.

### TECHNICAL FIELD

The present technology relates to semiconductor processes and equipment. More specifically, the present technology relates to cyclically etching silicon oxide material and silicon nitride material.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include flowing a fluorine-containing precursor and a hydrogen-containing precursor into a processing region of a semiconductor processing chamber. A substrate may be positioned within the processing region. The substrate may include a trench formed through stacked layers including alternating layers of silicon nitride and silicon oxide. The methods may include forming plasma effluents of the fluorine-containing precursor and the hydrogen-containing precursor. The methods may include contacting the substrate with the plasma effluents of the fluorine-containing precursor and the hydrogen-containing precursor. The contacting may form a fluorinated portion of the stacked layers. The methods may include flowing an inert precursor into the processing region of the semiconductor processing chamber. The methods may include forming plasma effluents of the inert precursor. The methods may include contacting the substrate with the plasma effluents of the inert precursor. The contacting may remove the fluorinated portion of the stacked layers. The methods may be performed at a chamber operating temperature of less than or about 20° C.

In some embodiments, the fluorine-containing precursor may be or include nitrogen trifluoride (NF₃). The hydrogen-containing precursor may be or include diatomic hydrogen (H₂). A flow rate ratio of the hydrogen-containing precursor relative to the fluorine-containing precursor may be greater than or about 2:1. The methods may include, prior to flowing the inert precursor, halting a flow of the fluorine-containing precursor and a flow of the hydrogen-containing precursor after a first period of time. The methods may include purging the processing region with a purge precursor. The first period of time may be less than or about 5 minutes. The plasma effluents of the fluorine-containing precursor and the hydrogen-containing precursor may be formed at less than or about 1,250 W. The inert precursor may be or include argon. The methods may include applying a bias power while contacting the stacked layers with the plasma effluents of the inert precursor. The bias power may be less than or about 1,250 W. The method may be performed at a chamber operating pressure of greater than or about 5 mTorr. The method may be performed at a chamber operating temperature of less than or about −20° C. The methods may include repeating the operations for at least two cycles.

Some embodiments of the present technology may encompass semiconductor processing methods. The methods may include i) flowing a fluorine-containing precursor and a hydrogen-containing precursor into a processing region of a semiconductor processing chamber. A substrate may be positioned within the processing region. The substrate may include a trench formed through stacked layers including alternating layers of silicon nitride and silicon oxide. The methods may include ii) forming plasma effluents of the fluorine-containing precursor and the hydrogen-containing precursor. The methods may include iii) contacting the stacked layers with the plasma effluents of the fluorine-containing precursor and the hydrogen-containing precursor. The contacting may form a fluorinated portion of the stacked layers. The methods may include iv) flowing an inert precursor into the processing region of the semiconductor processing chamber. The methods may include v) forming plasma effluents of the inert precursor. The methods may include vi) contacting the stacked layers with the plasma effluents of the inert precursor. The contacting may remove the fluorinated portion of the stacked layers. The methods may include vii) repeating operations i) through vi) for at least a second cycle.

In some embodiments, the fluorine-containing precursor may further include nitrogen. A flow rate of the fluorine-containing precursor may be less than or about 500 sccm. Operations i) through vi) may be repeated for at least ten cycles. The methods may be performed at a chamber operating temperature of less than or about −20° C.

Some embodiments of the present technology may encompass semiconductor processing methods. The methods may include flowing a fluorine-containing precursor and a hydrogen-containing precursor into a processing region of a semiconductor processing chamber. A substrate may be positioned within the processing region. The substrate may include a trench formed through stacked layers including alternating layers of silicon nitride and silicon oxide. A flow rate ratio of the hydrogen-containing precursor relative to the fluorine-containing precursor may be greater than or about 2:1. The methods may include forming plasma effluents of the fluorine-containing precursor and the hydrogen-containing precursor. The methods may include contacting the stacked layers with the plasma effluents of the fluorine-containing precursor and the hydrogen-containing precursor. The contacting may form a fluorinated portion of the stacked layers. The methods may include halting a flow of the fluorine-containing precursor and a flow of the hydrogen-containing precursor into the processing region. The methods may include flowing an inert precursor into the processing region of the semiconductor processing chamber. The methods may include forming plasma effluents of the inert precursor. The methods may include contacting the stacked layers with the plasma effluents of the inert precursor. The contacting may remove the fluorinated portion of the stacked layers. The fluorinated portion of the stacked layers may be characterized by a thickness of less than or about 100 nm.

In some embodiments, the methods may be performed at a chamber operating temperature of less than or about −40° C.

Such technology may provide numerous benefits over conventional systems and techniques. For example, the processes may etch stacked layers including alternating layers of silicon nitride and silicon oxide within semiconductor structures. Additionally, the processes may etch materials with polymer formation and may uniformly etch through stacked layers including alternating layers of silicon nitride and silicon oxide. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2A shows a schematic cross-sectional view of an exemplary processing chamber according to some embodiments of the present technology.

FIG. 2B shows a detailed view of a portion of the processing chamber illustrated in FIG. 2A according to some embodiments of the present technology.

FIG. 3 shows a bottom plan view of an exemplary showerhead according to some embodiments of the present technology.

FIG. 4 shows exemplary operations in a method according to some embodiments of the present technology.

FIGS. 5A-5D show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning from 2D NAND to 3D NAND, many process operations are modified from vertical to horizontal operations. Additionally, as 3D NAND structures grow in the number of cells being formed, the aspect ratios of memory holes and other structures increase, sometimes dramatically. During 3D NAND processing, stacks of placeholder layers and dielectric materials may form the inter-electrode dielectric or IPD layers. These placeholder layers may have a variety of operations performed to place structures before fully removing the material and replacing it with metal. For example, one or more memory holes or trenches may be etched into the stacks of placeholder layers and dielectric materials prior to removing the placeholder layers.

Many conventional technologies utilize an etch process that passivates sidewalls of the memory holes or trenches. By passivating the sidewalls, a uniform profile of the memory holes or trenches may be maintained, and lateral etching may be minimized. However, formation of the passivation material on the sidewalls, which may be a polymeric material, may not be uniform throughout a depth of the memory hole or trench. Accordingly, conventional technologies may suffer from pattern loading and/or bending. Further, conventional technologies forming polymeric passivation material may deposit polymeric material on the wafer bevel, which may result in arcing.

The present technology overcomes these issues by performing an etch process using cyclic exposure first to a fluorine-containing precursor and hydrogen-containing precursor and second to an inert precursor. The etch process may be formed at a low temperature that increases directionality of the etch without the need for polymeric passivation material. Due to the high directionality of the etch, issues with memory hole or trench profile are reduced and/or eliminated. Additionally, arcing is mitigated since polymeric material is not being inadvertently deposited on the wafer bevel.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described.

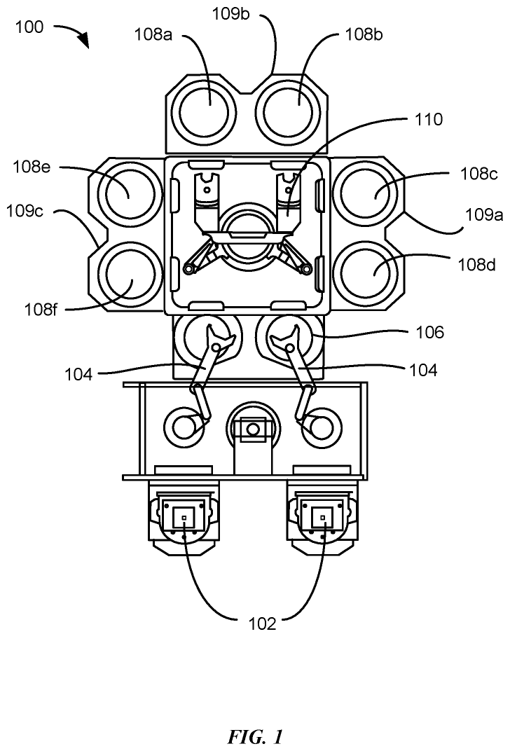

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in one or more chambers separated from the fabrication system shown in different embodiments. It will be appreciated that additional configurations of deposition, etching, annealing, and curing chambers for dielectric films are contemplated by system 100.

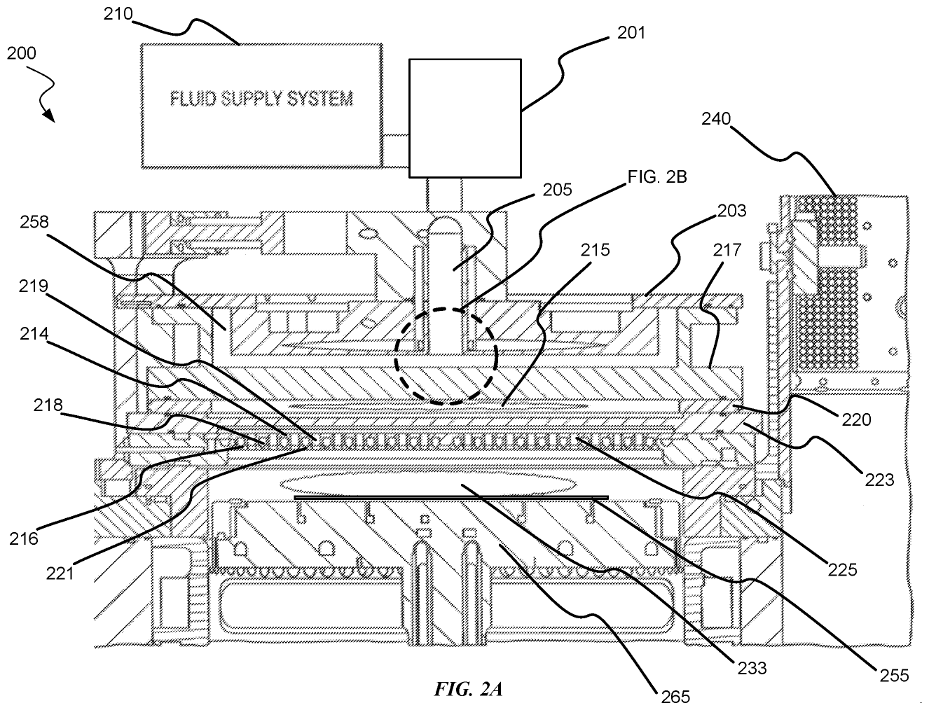

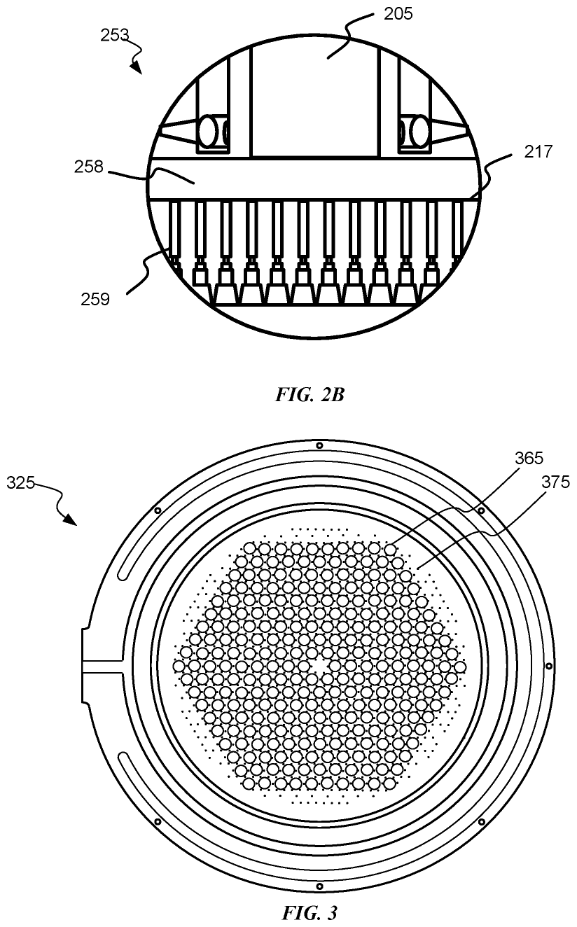

FIG. 2A shows a cross-sectional view of an exemplary process chamber system 200 with partitioned plasma generation regions within the processing chamber, and which may be configured to perform processes as described further below. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel may bypass the RPS 201, if included.

A cooling plate 203, faceplate 217, ion suppressor 223, showerhead 225, and a pedestal 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205. In some embodiments, additional plasma sources may be utilized including inductively-coupled plasma sources extending about the chamber or in fluid communication with the chamber, as well as additional plasma-generating systems.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiNx:SiOx etch ratios, Si:SiOx etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A-2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

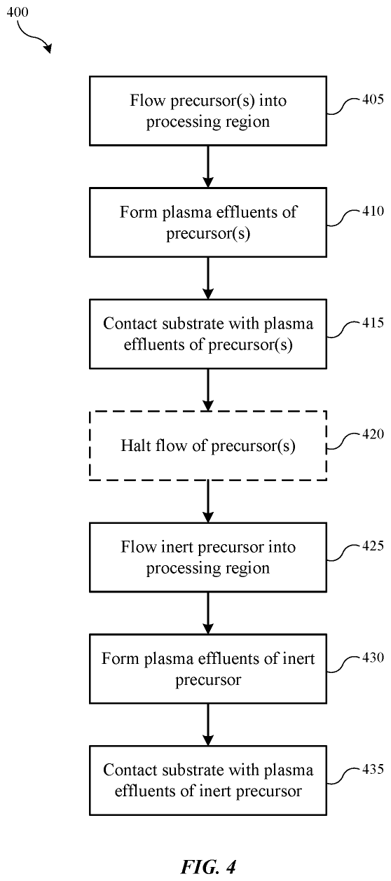

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the showerhead 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

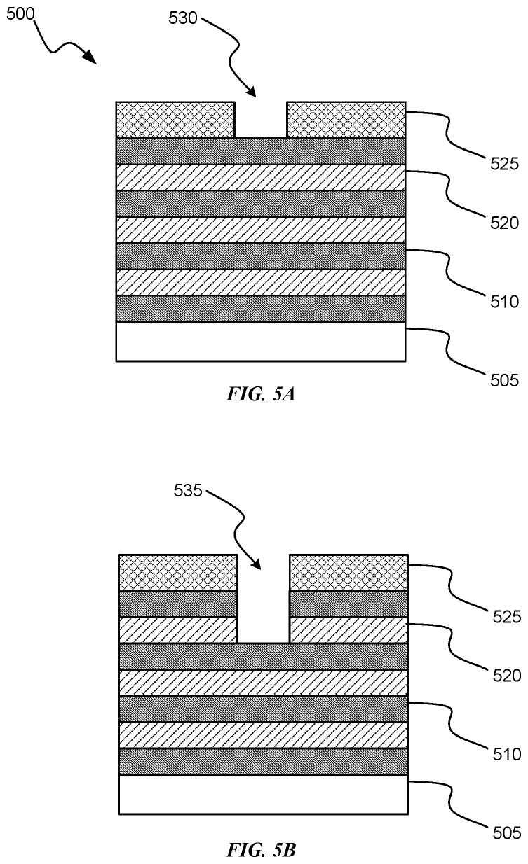

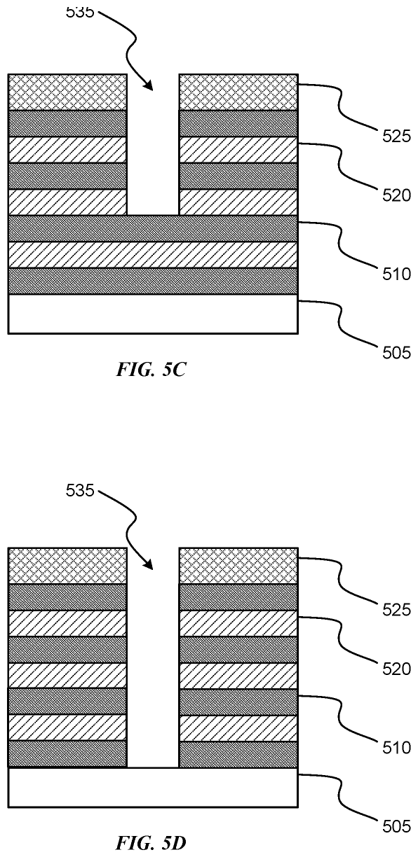

The chamber discussed previously may be used in performing exemplary methods, including etching methods, although any number of chambers may be configured to perform one or more aspects used in embodiments of the present technology. Turning to FIG. 4, exemplary operations in a method 400 according to embodiments of the present technology are shown. Method 400 may include one or more operations prior to the initiation of the method, including front end processing, deposition, etching, polishing, cleaning, or any other operations that may be performed prior to the described operations. The methods may include a number of optional operations, which may or may not be specifically associated with some embodiments of methods, according to embodiments of the present technology. For example, many of the operations are described in order to provide a broader scope of the processes performed, but are not critical to the technology, or may be performed by alternative methodology as will be discussed further below. Method 400 may describe operations shown schematically in FIGS. 5A-5D, the illustrations of which will be described in conjunction with the operations of method 400. It is to be understood that the figures illustrate only partial schematic views, and a substrate may contain any number of additional materials and features having a variety of characteristics and aspects as illustrated in the figures.

Method 400 may or may not involve optional operations to develop the semiconductor structure to a particular fabrication operation. It is to be understood that method 400 may be performed on any number of semiconductor structures 500 or substrates 505, as illustrated in FIG. 5A, including exemplary structures on which a silicon oxide and silicon nitride etching operation may be performed. As illustrated in FIG. 5A, substrate 505 may have a plurality of stacked layers overlying the substrate, which may be silicon, silicon germanium, or other substrate materials. The layers may include IPD layers including dielectric material 510, which may be silicon oxide, in alternating layers with placeholder material 520, which may be silicon nitride or polysilicon, for example. Placeholder material 520 may be or include material that will be removed to produce individual memory cells in subsequent operations. Although the remaining disclosure will discuss silicon nitride and silicon oxide IPD layers, any other known materials used in these two layers may be substituted for one or more of the layers. Although illustrated with only 7 layers of material, exemplary structures may include any of the numbers of layers including hundreds of layers of material, and it is to be understood that the figures are only schematics to illustrate aspects of the present technology. Additionally, to allow for one or more memory holes or trenches to be formed through the IPD layers, a mask material 525 may be formed on the alternating layers of the dielectric material 510 and the placeholder material 520. The mask material 525 may be patterned to form one or more apertures 530, exposing a portion the underlying IPD layers. Although only a single aperture 530 is illustrated, it is to be understood that exemplary structure 500 may include any number of apertures across the substrate 505. Some or all of these operations may be performed in chambers or system tools as previously described, or may be performed in different chambers on the same system tool, which may include the chamber in which the operations of method 400 are performed.

Method 400 may be performed to etch or otherwise remove portions of the dielectric material 510 and the placeholder material 520, which may form memory holes or trenches in the structure 500 as illustrated. The method may be performed to facilitate control of the profile through the structure, and improve etch characteristics, such as uniformity of the memory holes or trenches as the etch progresses into the alternating layers. Method 400 may include flowing a fluorine-containing precursor and a hydrogen-containing precursor into a processing region of the semiconductor processing chamber in which the substrate is maintained at operation 405. Plasma effluents of the fluorine-containing precursor and the hydrogen-containing precursor may be formed at operation 410. The plasma effluents of the fluorine-containing precursor and the hydrogen-containing precursor may contact the substrate at operation 410, and may form a fluorinated portion of the stacked layers of the dielectric material 510 and the placeholder material 520.

In embodiments, method 400 may include halting a flow of the fluorine-containing precursor and a flow of the hydrogen-containing precursor after a first period of time at optional operation 420. Method 400 may also include purging the processing region with a purge precursor after halting the flow of the fluorine-containing precursor and the flow of the hydrogen-containing precursor. After fluorinating a portion of the stacked layers, and optionally halting the flow of the fluorine-containing precursor and the flow of the hydrogen-containing precursor, method 400 may include flowing an inert precursor into the processing region of the semiconductor processing chamber at operation 425. Plasma effluents of the inert precursor may be formed at operation 430. As illustrated in FIG. 5B, the plasma effluents of the inert precursor may contact the substrate at operation 435, and may remove the fluorinated portion of the stacked layers of the dielectric material 510 and the placeholder material 520. Removing the fluorinated portion of the stacked layers of the dielectric material 510 and the placeholder material 520 may begin to form a memory hole or trench 535 in the stacked layers. The memory hole or trench 535 may be in alignment with the aperture 530 in the mask material 525. Again, although only a single memory hole or trench 535 is illustrated, it is to be understood that exemplary structure 500 may include any number of memory holes or trenches across the substrate 505.

As illustrated in FIGS. 5C-5D, the operations of method 400 may be repeated for a second cycle and may be repeated for any number of cycles. The number of cycles may be dependent on a desired depth of the memory hole or trench 535. In embodiments, the depth of the memory hole or trench 535 may extend through all of the stacked layers of the dielectric material 510 and the placeholder material 520, which may ultimately expose substrate 505.

Fluorine-containing precursors flowed at operation 405 may include hydrogen fluoride (HF), nitrogen trifluoride (NF₃), diatomic fluorine (F₂), bromine trifluoride (BrF₃), chlorine trifluoride (ClF₃), sulfur hexafluoride (SF₆), xenon difluoride (XeF₂), carbon tetrafluoride (CF₄), or any organofluoride, or any other fluorine-containing precursor used or useful in semiconductor processing. In some embodiments, the fluorine-containing precursor may include nitrogen. Hydrogen-containing precursors flowed at operation 405 may include diatomic hydrogen (H₂), ammonia (NH₃), steam (H₂O), methane (CH₄) or any other hydrogen-containing precursor used or useful in semiconductor processing. The fluorine-containing precursor and the hydrogen-containing precursor may also be flowed with any number of additional precursors or carrier gases including nitrogen, argon, helium, or any number of additional materials, although in some embodiments the precursors may be limited to control side reactions or other aspects that may impact the fluorination.

A flow rate ratio of the hydrogen-containing precursor relative to the fluorine-containing precursor may be adjusted to control the fluorination and subsequent etch of the stacked layers of the dielectric material 510 and the placeholder material 520. At increased flow rate ratios of the hydrogen-containing precursor relative to the fluorine-containing precursor etch amount per cycle may increase. Additionally, a synergistic effect between the fluorination and subsequent removal may be achieved. Accordingly, the flow rate ratio of the hydrogen-containing precursor relative to the fluorine-containing precursor may be greater than or about 2:1, and may be greater than or about 2.5:1, greater than or about 3:1, greater than or about 3.5:1, greater than or about 4:1, greater than or about 4.5:1, greater than or about 5:1, greater than or about 5.5:1, or more. However, at very high flow rate ratios of the hydrogen-containing precursor relative to the fluorine-containing precursor, saturation may occur as the fluorine-containing precursor may not be able to penetrate deeper into the stacked layers of the dielectric material 510 and the placeholder material 520.

The flow rate of the fluorine-containing precursor may be less than or about 500 sccm, and may be less than or about 475 sccm, less than or about 450 sccm, less than or about 425 sccm, less than or about 400 sccm, less than or about 375 sccm, less than or about 350 sccm, less than or about 325 sccm, less than or about 300 sccm, less than or about 275 sccm, less than or about 250 sccm, or less. At flow rates greater than, for example, 500 sccm, excessive fluorine may be present and may result in excessive etching. For example, excessive fluorine may result in lateral etching that may impact uniformity of the fluorination and subsequent etch. Further, to dilute the fluorine-containing precursor, a flow rate of the hydrogen-containing precursor may be greater than or about 5 sccm, and may be greater than or about 10 sccm, greater than or about 20 sccm, greater than or about 30 sccm, greater than or about 40 sccm, greater than or about 50 sccm, or more.

The plasma power used to form plasma effluents of the fluorine-containing precursor and the hydrogen-containing precursor may be a relatively low plasma power. The relatively low plasma power may allow for formation of HF molecules. At higher plasma powers, HF may fragment and the etch amount per cycle may reduce. Accordingly, the plasma effluents of the fluorine-containing precursor and the hydrogen-containing precursor may be formed at less than or about 1,500 W, and may be formed at less than or about 1,400 W, less than or about 1,300 W, less than or about 1,250 W, less than or about 1,200 W, less than or about 1,100 W, less than or about 1,000 W, or less. However, very low plasma powers may result in low plasma density. Therefore, the plasma effluents of the fluorine-containing precursor and the hydrogen-containing precursor may be formed at greater than or about 500 W, and may be formed at greater than or about 600 W, greater than or about 700 W, greater than or about 750 W, greater than or about 800 W, greater than or about 900 W, greater than or about 1,000 W, or more.

As previously discussed, the contacting at operation 415 may form a fluorinated portion of the stacked layers of the dielectric material 510 and the placeholder material 520. For example, the contacting may form a silicon-oxygen-and-fluorine-containing material and/or a silicon-nitrogen-and-fluorine-containing material. The fluorinated portion of the stacked layers of the dielectric material 510 and the placeholder material 520 may be a reactive layer that may be subsequently removed by contacting the substrate with plasma effluents of the inert precursor.

The fluorination operations may be continued for a first period of time in some embodiments. The first period of time may be sufficient to produce a reactive layer in the stacked layers of the dielectric material 510 and the placeholder material 520, while limiting residence time that may begin to saturate the fluorination. For example, the first period of time may be greater than or about 1 second, and may be greater than or about 2 seconds, greater than or about 3 seconds, greater than or about 4 seconds, greater than or about 5 seconds, greater than or about 10 seconds, greater than or about 15 seconds, greater than or about 20 seconds, greater than or about 25 seconds, greater than or about 30 seconds, or more. However, at increased periods of time, the fluorine may no longer be able to penetrate the stacked layers of the dielectric material 510 and the placeholder material 520 and additional residence time may not realize an increased benefit. Accordingly, to maintain efficiency, the first period of time may be less than or about 5 minutes, and may be less than or about 3 minutes, less than or about 1 minute, less than or about 55 seconds, less than or about 50 seconds, less than or about 45 seconds, less than or about 40 seconds, less than or about 35 seconds, less than or about 30 seconds, or less.

Subsequent the first period of time, the flow of the fluorine-containing precursor and/or the flow of the hydrogen-containing precursor may be halted along with formation of the plasma effluents thereof. A purge may then be performed, which may remove residual etchant materials, etch byproducts, or other materials from the processing region. The purge may be performed with any number of materials that may be chemically inert, such as nitrogen or noble gases, which may be used to purge the processing region of the semiconductor processing chamber. The purging process may improve throughput by expediting removal of byproducts as well as less beneficial plasma effluents, and reduce the residence time of these materials within the processing region. This may facilitate the directional etching of the stacked layers of the dielectric material 510 and the placeholder material 520.

Inert precursors flowed at operation 425 may include nitrogen, argon, helium, xenon, or other noble gases, or any chemically inert material used or useful in semiconductor processing. The flow rate of the inert precursor may be less than or about 500 sccm, and may be less than or about 475 sccm, less than or about 450 sccm, less than or about 425 sccm, less than or about 400 sccm, less than or about 375 sccm, less than or about 350 sccm, less than or about 325 sccm, less than or about 300 sccm, less than or about 275 sccm, less than or about 250 sccm, or less.

The plasma power used to form plasma effluents of the inert precursor may be similar to the plasma power used at operation 410 and may be a relatively low plasma power. More specifically, the plasma effluents of the inert precursor may be formed at less than or about 1,500 W, and may be formed at less than or about 1,400 W, less than or about 1,300 W, less than or about 1,250 W, less than or about 1,200 W, less than or about 1,100 W, less than or about 1,000 W, or less. Similarly, the plasma effluents of the inert precursor may be formed at greater than or about 500 W, and may be formed at greater than or about 600 W, greater than or about 700 W, greater than or about 750 W, greater than or about 800 W, greater than or about 900 W, greater than or about 1,000 W, or more.

While forming the plasma effluents of the inert precursor at operation 430 and/or while contacting the substrate with the plasma effluents of the inert precursor at operation 435, a bias power may be applied. The bias power, which may be a 2 MHz frequency applied to the pedestal or substrate support, may increase directionality of the plasma effluents of the inert precursor. The increased directionality may draw the plasma effluents of the inert precursor fluorinated portion of the stacked layers of the dielectric material 510 and the placeholder material 520. Accordingly, the plasma effluents of the inert precursor may bombard and remove the fluorinated portion of the stacked layers of the dielectric material 510 and the placeholder material 520. In embodiments, the bias power applied may be greater than or about 500 W, and may be formed at greater than or about 600 W, greater than or about 700 W, greater than or about 750 W, greater than or about 800 W, greater than or about 900 W, greater than or about 1,000 W, or more. However, at higher bias powers, the bombardment may increase and materials on substrate 505 or in structure 500 may begin to sputter. Accordingly, the bias power applied may be less than or about 1,500 W, and may be formed at less than or about 1,400 W, less than or about 1,300 W, less than or about 1,250 W, less than or about 1,200 W, less than or about 1,100 W, less than or about 1,000 W, or less.

As previously discussed, the contacting at operation 435 may remove the fluorinated portion of the stacked layers of the dielectric material 510 and the placeholder material 520. For example, the contacting may bombard the structure 500 and substrate 505 with plasma effluents of the inert precursor. This bombardment and resultant physical interaction may etch the fluorinated portion of the stacked layers of the dielectric material 510 and the placeholder material 520. More specifically, ion-driven desorption may cause the fluorinated portion of the stacked layers of the dielectric material 510 and the placeholder material 520 to be removed.

In embodiments, a thickness of the stacked layers of the dielectric material 510 and the placeholder material 520 that may be fluorinated and subsequently removed may be less than or about 150 nm, and may be less than or about 125 nm, less than or about 100 nm, less than or about 90 nm, less than or about 80 nm, less than or about 70 nm, less than or about 60 nm, less than or about 50 nm, less than or about 40 nm, less than or about 30 nm, or less. The thickness of the stacked layers that may be fluorinated and subsequently removed may be limited by the ability of the fluorine-containing precursor to diffuse through the stacked layers of the dielectric material 510 and the placeholder material 520. For example, longer periods of time exposing the stacked layers to the fluorine-containing precursor may increase the thickness, but the effect of fluorine-containing precursor may be limited at a certain depth of the stacked layers.

By performing an amount of fluorination followed by an amount of removal or etch, a controlled directional etch of the stacked layers of the dielectric material 510 and the placeholder material 520 may be performed. As illustrated in FIGS. 5C-5D, to further facilitate directional etching, the present technology may be performed in a number of cycles to allow efficient fluorination and subsequent removal of the stacked layers of the dielectric material 510 and the placeholder material 520. In some embodiments, method 400 may include repeating the operations 405-435 for at least two cycles, and may include repeating the operations 405-435 for at least three cycles, at least four cycles, at least five cycles, at least ten cycles, at least fifteen cycles, at least twenty cycles, or more. It is contemplated that the operations 405-435 of method 400 may be repeated any number of times depending on depth of the memory hole or trench 535 to be etched.

Process conditions may also impact the operations performed in method 400. Each of the operations of method 400 may be performed during a constant temperature in embodiments, while in some embodiments the temperature may be adjusted during different operations. Temperatures may be maintained in any range, however, at higher temperatures, a thinner reactive layer or fluorinated portion of the stacked layers of the dielectric material 510 and the placeholder material 520 may result. As amount or thicknesses of fluorination decreases, throughput may decrease, and queue times may increase. Additionally, at lower temperatures, water (H2O), a byproduct from the removal of silicon oxide, may condense on the stacked layers of the dielectric material 510 and the placeholder material 520 and serve to accelerate the etch. Accordingly, in some embodiments any or all operations of the method 400 may performed at a chamber operating temperature of less than or about 20° C., and may be performed at a chamber operating temperature of less than or about 10° C., less than or about 0° C., less than or about −10° C., less than or about −20° C., less than or about −30° C., less than or about −40° C., less than or about −50° C., less than or about −60° C., less than or about −70° C., less than or about −80° C., or less.

Each of the operations of method 400 may be performed during a constant pressure in embodiments, while in some embodiments the pressure may be adjusted during different operations. Pressures may be maintained in any range, however, at higher pressures, further dissociation of the fluorine-containing precursors may occur, which may produce more fluorine radicals. As the amount of fluorine radicals increases, directionality of the etch may decrease and the profile of the memory hole or trench 535 may suffer. Accordingly, in some embodiments any or all operations of the method 400 may performed at a chamber operating pressure of greater than or about 5 mTorr, and may be performed at a chamber operating pressure of greater than or about 10 mTorr, greater than or about 15 mTorr, greater than or about 20 mTorr, greater than or about 25 mTorr, greater than or about 30 mTorr, greater than or about 35 mTorr, greater than or about 40 mTorr, greater than or about 45 mTorr, greater than or about 50 mTorr, greater than or about 55 mTorr, greater than or about 60 mTorr, or more. Conversely, at lower pressures, directionality of the etch may increase as well as ion energy and etch amount per cycle. Therefore, any or all operations of the method 400 may performed at a chamber operating pressure of less than or about 75 mTorr, and may be performed at a chamber operating pressure of less than or about 70 mTorr, less than or about 65 mTorr, less than or about 60 m Torr, less than or about 55 mTorr, less than or about 50 mTorr, less than or about 45 mTorr, less than or about 40 mTorr, less than or about 35 mTorr, less than or about 30 mTorr, or less.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
flowing a fluorine-containing precursor and a hydrogen-containing precursor into a processing region of a semiconductor processing chamber, wherein a substrate is positioned within the processing region, and wherein the substrate comprises a trench formed through stacked layers including alternating layers of silicon nitride and silicon oxide;
forming plasma effluents of the fluorine-containing precursor and the hydrogen-containing precursor;
contacting the substrate with the plasma effluents of the fluorine-containing precursor and the hydrogen-containing precursor, wherein the contacting forms a fluorinated portion of the stacked layers;
flowing an inert precursor into the processing region of the semiconductor processing chamber;
forming plasma effluents of the inert precursor; and
contacting the substrate with the plasma effluents of the inert precursor, wherein the contacting removes the fluorinated portion of the stacked layers, and wherein the method is performed at a chamber operating temperature of less than or about 20° C.

2. The semiconductor processing method of claim 1, wherein the fluorine-containing precursor comprises nitrogen trifluoride (NF₃).

3. The semiconductor processing method of claim 1, wherein the hydrogen-containing precursor comprises diatomic hydrogen (H₂).

4. The semiconductor processing method of claim 1, wherein a flow rate ratio of the hydrogen-containing precursor relative to the fluorine-containing precursor is greater than or about 2:1.

5. The semiconductor processing method of claim 1, further comprising:
prior to flowing the inert precursor, halting a flow of the fluorine-containing precursor and a flow of the hydrogen-containing precursor after a first period of time; and
purging the processing region with a purge precursor.

6. The semiconductor processing method of claim 5, wherein the first period of time is less than or about 5 minutes.

7. The semiconductor processing method of claim 1, wherein the plasma effluents of the fluorine-containing precursor and the hydrogen-containing precursor are formed at less than or about 1,250 W.

8. The semiconductor processing method of claim 1, wherein the inert precursor comprises argon.

9. The semiconductor processing method of claim 1, further comprising:
applying a bias power while contacting the stacked layers with the plasma 2 effluents of the inert precursor.

10. The semiconductor processing method of claim 9, wherein the bias power is less than or about 1,250 W.

11. The semiconductor processing method of claim 1, wherein the method is performed at a chamber operating pressure of greater than or about 5 mTorr.

12. The semiconductor processing method of claim 1, wherein the method is performed at a chamber operating temperature of less than or about −20° C.

13. The semiconductor processing method of claim 1, further comprising:
repeating the operations for at least two cycles.

14. A semiconductor processing method comprising:
i) flowing a fluorine-containing precursor and a hydrogen-containing precursor into a processing region of a semiconductor processing chamber, wherein a substrate is positioned within the processing region, and wherein the substrate comprises a trench formed through stacked layers including alternating layers of silicon nitride and silicon oxide;
ii) forming plasma effluents of the fluorine-containing precursor and the hydrogen-containing precursor;
iii) contacting the stacked layers with the plasma effluents of the fluorine-containing precursor and the hydrogen-containing precursor, wherein the contacting forms a fluorinated portion of the stacked layers;
iv) flowing an inert precursor into the processing region of the semiconductor processing chamber;
v) forming plasma effluents of the inert precursor;
vi) contacting the stacked layers with the plasma effluents of the inert precursor, wherein the contacting removes the fluorinated portion of the stacked layers; and
vii) repeating operations i) through vi) for at least a second cycle.

15. The semiconductor processing method of claim 14, wherein the fluorine-containing precursor further comprises nitrogen.

16. The semiconductor processing method of claim 14, wherein a flow rate of the fluorine-containing precursor is less than or about 500 sccm.

17. The semiconductor processing method of claim 14, operations i) through vi) are repeated for at least ten cycles.

18. The semiconductor processing method of claim 14, wherein the method is performed at a chamber operating temperature of less than or about −20° C.

19. A semiconductor processing method comprising:
flowing a fluorine-containing precursor and a hydrogen-containing precursor into a processing region of a semiconductor processing chamber, wherein a substrate is positioned within the processing region, wherein the substrate comprises a trench formed through stacked layers including alternating layers of silicon nitride and silicon oxide, and wherein a flow rate ratio of the hydrogen-containing precursor relative to the fluorine-containing precursor is greater than or about 2:1;
forming plasma effluents of the fluorine-containing precursor and the hydrogen-containing precursor;
contacting the stacked layers with the plasma effluents of the fluorine-containing precursor and the hydrogen-containing precursor, wherein the contacting forms a fluorinated portion of the stacked layers;
halting a flow of the fluorine-containing precursor and a flow of the hydrogen-containing precursor into the processing region;
flowing an inert precursor into the processing region of the semiconductor processing chamber;
forming plasma effluents of the inert precursor; and
contacting the stacked layers with the plasma effluents of the inert precursor, wherein the contacting removes the fluorinated portion of the stacked layers, wherein the fluorinated portion of the stacked layers is characterized by a thickness of less than or about 100 nm.

20. The semiconductor processing method of claim 19, wherein the method is performed at a chamber operating temperature of less than or about −40° C.
